(19) United States
(12) Patent Application Publication
(10) Pub. No.: US 2025/0393216 A1
(43) Pub. Date: Dec. 25, 2025

(54) THREE-DIMENSIONAL MEMORY ARRAY AND MANUFACTURING METHOD THEREFOR, AND ELECTRONIC APPARATUS

(71) Applicant: CXMT Corporation, Hefei City (CN)

(72) Inventors: Huihui LI, Hefei City (CN); Zelun LI, Hefei City, (CN); Hao MENG, Hefei City (CN); KAI HUNG ALEX SEE, Hefei City (CN)

(73) Assignee: CXMT Corporation, Hefei City (CN)

(21) Appl. No.: 18/945,461

(22) Filed: Nov. 12, 2024

Related U.S. Application Data
(63) Continuation of application No. PCT/CN2024/119538, filed on Sep. 19, 2024.

(30) Foreign Application Priority Data
Jun. 25, 2024 (CN) 202410831274.9

(51) Int. Cl. H10B 51/20; G11C 11/22; H01L 21/28; H10B 51/30

(52) U.S. Cl. CPC H10B 51/20; G11C 11/223; H10B 51/30; H10D 64/033

(57) ABSTRACT

A three-dimensional memory array includes a first memory cell array including a plurality of memory cells stacked along a vertical direction, a plurality of word lines, and at least one bit line. Each memory cell includes a transistor and a storage node coupled in a horizontal direction and connected in parallel to each other. The transistors in the plurality of memory cells, and/or the storage nodes in the plurality of memory cells in the vertical direction are connected in series to each other. The plurality of word lines are spaced apart along the vertical direction and connected to the transistors in the plurality of memory cells in the vertical direction, respectively. The bit line extends along the vertical direction and is connected to the transistors in the plurality of memory cells in the vertical direction.

This is a continuation of International Application No. PCT/CN2024/119538 filed on Sep. 19, 2024, which claims priority to Chinese Patent Application No. 202410831274.9, filed on Jun. 25, 2024. The disclosures of the above-referenced applications are hereby incorporated by reference in their entirety.

### BACKGROUND

The development of the memory pursues performance indicators, such as high speed, high integration density, and low power consumption. As the dimension of the structure of the semiconductor device shrinks, technical barriers encountered by the existing structure are increasingly obvious. Therefore, it is an advantageous way to break the existing technical barriers by developing more novel structures on the basis of the existing structure.

The appearance of the three-dimensional memory meets the above requirements; however, there is a serious crosstalk problem between adjacent storage bits in the three-dimensional memory. Accordingly, the power consumption is significantly increased, the read-write window and the read-write speed are reduced, and the wiring is complex. Besides, the footprint is large, and the effective area of the memory array is reduced, thus affecting the device performance.

### SUMMARY

Embodiments of the present disclosure relate to the technical field of semiconductors, in particular to a three-dimensional memory array and a manufacturing method therefor, and an electronic apparatus.

According to a first aspect of embodiments of the present disclosure, a three-dimensional memory array is provided. The three-dimensional memory array includes a first memory cell array (MA). The MA includes: a plurality of memory cells stacked along a vertical direction, a plurality of word lines (WL), and at least one bit line (BL). Each one of the plurality of memory cells includes a transistor (TR) and a storage node (SN) coupled in a horizontal direction and connected in parallel to each other. The TRs in the plurality of memory cells in the vertical direction are connected in series to each other, and/or the SNs in the plurality of memory cells in the vertical direction are connected in series to each other. The plurality of WLs are spaced apart along the vertical direction and connected to the TRs in the plurality of memory cells in the vertical direction, respectively. The BL extends along the vertical direction and is connected to the TRs in the plurality of memory cells in the vertical direction.

According to a second aspect of the embodiments of the present disclosure, a method for manufacturing a three-dimensional memory array is provided. The method includes forming a first memory cell array (MA). Forming the MA includes: forming a plurality of memory cells stacked along a vertical direction; forming a plurality of word lines (WLs) spaced apart along the vertical direction; and forming at least one bit line (BL) extending along the vertical direction. Each one of the plurality of memory cells includes a transistor (TR) and a storage node (SN) coupled in a horizontal direction and connected in parallel to each other. The TRs in the plurality of memory cells in the vertical direction are connected in series to each other, and/or the SNs in the plurality of memory cells in the vertical direction are connected in series to each other. The plurality of WLs are connected to the TRs in the plurality of memory cells in the vertical direction, respectively. The BL is connected to the TRs in the plurality of memory cells in the vertical direction.

According to a third aspect of the embodiments of the present disclosure, an electronic apparatus is provided. The electronic apparatus includes: a processing device; and a memory device electrically connected to the processing device. The memory device includes the above three-dimensional memory array and a controller configured to control reading and writing of the three-dimensional memory array.

### BRIEF DESCRIPTION OF THE DRAWINGS

FIG. 1 is a schematic view of a circuit of a three-dimensional memory array according to an exemplary embodiment;

FIG. 2 is a perspective view of a three-dimensional memory array according to an exemplary embodiment;

FIG. 3 is a schematic plan view of the three-dimensional memory array in FIG. 2;

FIG. 4 is a perspective view of a three-dimensional memory array according to yet another exemplary embodiment;

FIG. 5 is a schematic view of forming a stack layer on a substrate in a process of manufacturing a semiconductor device according to an exemplary embodiment, wherein 5a is a schematic plan view, and 5b is a schematic cross-sectional diagram;

FIG. 6 is a schematic view of forming at least one first trench penetrating through a stack layer in a process of manufacturing a semiconductor device according to an exemplary embodiment, wherein 6a is a schematic plan view, and 6b is a schematic cross-sectional view;

FIG. 7 is a schematic view of forming a first isolation layer in at least one first trench in a process of manufacturing a semiconductor device according to an exemplary embodiment, wherein 7a is a schematic plan view, and 7b is a schematic cross-sectional view;

FIG. 8 is a schematic view of forming at least two second trenches penetrating through a stack layer in a process of manufacturing a semiconductor device according to an exemplary embodiment, wherein 8a is a schematic plan view, and 8b is a schematic cross-sectional view;

FIG. 9 is a schematic view of forming a plurality of side cavities in a process of manufacturing a semiconductor device according to an exemplary embodiment, wherein 9a is a schematic plan view, and 9b is a schematic cross-sectional view;

FIG. 10 is a schematic view of filling an insulating dielectric material in a process of manufacturing a semiconductor device according to an exemplary embodiment, wherein 10a is a schematic plan view, and 10b is a schematic cross-sectional view;

FIG. 11 is a schematic view of forming an insulating dielectric layer in a plurality of side cavities separately in a process of manufacturing a semiconductor device according to an exemplary embodiment, wherein 11a is a schematic plan view, and 11b is a schematic cross-sectional view;

FIG. 12 is a schematic view of conformally forming a semiconductor layer on surfaces of a plurality of insulating dielectric layers in a process of manufacturing a semiconductor device according to an exemplary embodiment, wherein 12a is a schematic plan view, and 12b is a schematic cross-sectional view;

FIG. 13 is a schematic view of forming a dielectric layer on a surface of a semiconductor layer in a process of manufacturing a semiconductor device according to an exemplary embodiment, wherein 13a is a schematic plan view, and 13b is a schematic cross-sectional view;

FIG. 14 is a schematic view of depositing a gate material in a process of manufacturing a semiconductor device according to an exemplary embodiment, wherein 14a is a schematic plan view, and 14b is a schematic cross-sectional view;

FIG. 15 is a schematic view of forming a plurality of gates in a process of manufacturing a semiconductor device according to an exemplary embodiment, wherein 15a is a schematic plan view, and 15b is a schematic cross-sectional view;

FIG. 16 is a schematic view of forming a third mask layer covering an entire structure and provided with at least one third opening in a process of manufacturing a semiconductor device according to an exemplary embodiment, wherein 16a is a schematic plan view, and 16b is a schematic cross-sectional view;

FIG. 17 is a schematic view of forming at least one third trench in a process of manufacturing a semiconductor device according to an exemplary embodiment, wherein 17a is a schematic plan view, and 17b is a schematic cross-sectional view;

FIG. 18 is a schematic view of forming an isolation layer along at least one third trench in a process of manufacturing a semiconductor device according to an exemplary embodiment, wherein 18a is a schematic plan view, and 18b is a schematic cross-sectional view; and

FIG. 19 is a schematic structural view of an electronic apparatus according to an exemplary embodiment.

### DETAILED DESCRIPTION

The technical solutions of the present disclosure will be further elaborated below with reference to the drawings and embodiments. While exemplary implementations of the present disclosure are shown in the drawings, it should be understood that the present disclosure may be implemented in various forms and should not be limited by the embodiments set forth herein. Rather, these embodiments are provided so that the present disclosure will be more thoroughly understood and the scope of the present disclosure will be fully conveyed to those skilled in the art.

The present disclosure is more specifically described in the following paragraphs with reference to the drawings by way of example. Advantages and features of the present disclosure will become apparent from the following description and claims. It should be noted that the drawings are all in a very simplified form and not to precise scale, and are provided only for the purpose of facilitating a convenient and clear description of the embodiments of the present disclosure.

It will be understood that the meaning of “on”, “above”, and “over” in the present disclosure should be interpreted in the broadest manner such that “on” not only includes the meaning of “on” something with no intermediate feature or layer therebetween (i.e., directly on something) but also includes the meaning of “on” something with an intermediate feature or a layer therebetween.

In the embodiments of the present disclosure, the terms “first”, “second”, “third”, and the like are used for distinguishing similar objects and are not necessarily used for describing a particular order or sequence.

In the embodiments of the present disclosure, the term “layer” refers to a material portion that includes a region having a thickness. A layer may extend over the entirety of the underlying or overlying structure or may have an extent that is less than the extent of the underlying or overlying structure. Furthermore, a layer may be a region of a homogeneous or inhomogeneous continuous structure having a thickness less than the thickness of a continuous structure. For example, a layer may be arranged between a top surface and a bottom surface of a continuous structure, or a layer may be arranged between any pair of horizontal planes at the top surface and the bottom surface of the continuous structure. A layer may extend horizontally, perpendicularly, and/or along inclined surfaces. A layer may include a plurality of sub-layers.

It should be noted that unless conflicting, the technical solutions described in the embodiments of the present disclosure may be arbitrarily combined.

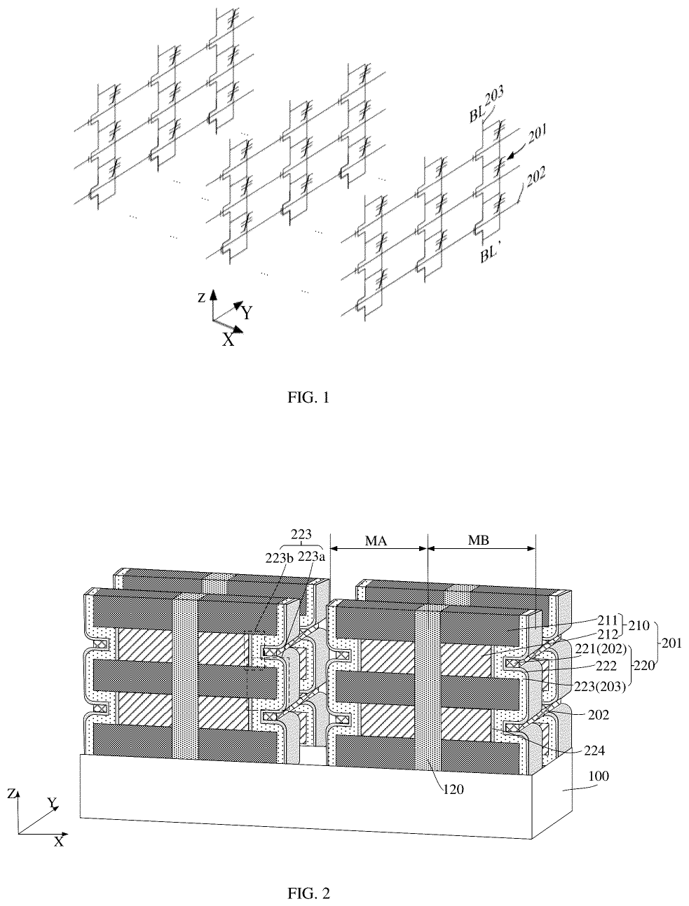

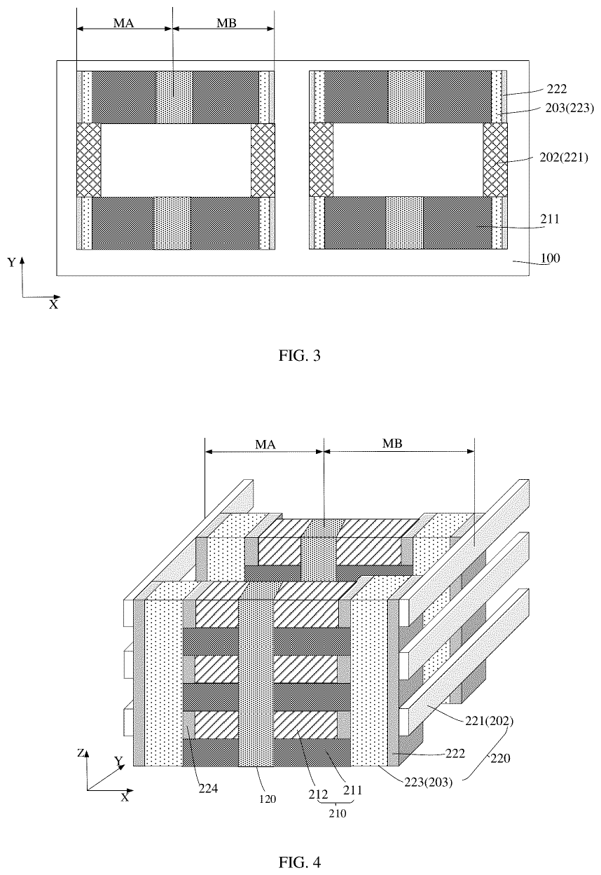

FIG. 1 is a schematic view of a circuit of a three-dimensional memory array according to an exemplary embodiment. FIG. 2 is a perspective view of a three-dimensional memory array according to an exemplary embodiment. FIG. 3 is a schematic plan view of the three-dimensional memory array in FIG. 2.

With reference to FIG. 1 to FIG. 3, a three-dimensional memory array in the embodiments of the present disclosure includes a substrate 100 and a plurality of memory cell arrays arranged on the substrate 100. The plurality of memory cell arrays may, for example, include MAs and MBs. The MAs and the MBs are alternately spaced apart on the substrate 100, thus forming, for example, a three-dimensional memory array of MA, MB, MA, MB alternately arranged. These memory cell arrays are isolated from each other by isolation structures. The isolation structures may include at least one of silicon oxide, silicon nitride, or silicon oxynitride (FIG. 2 shows a perspective view of the three-dimensional memory array, and thus part of the isolation structures is omitted). The MA and the MB are mirror symmetrical to each other. Each one of the memory cell arrays, such as the MA, includes a plurality of memory cells 201, a plurality of WLs 202, and at least one BL 203. The plurality of memory cells 201 in the embodiments of the present disclosure are stacked along a vertical direction Z. Each memory cell 201 includes one TR 220 and one SN 210. The TR 220 and the SN 210 are coupled in a horizontal direction, e.g., a first horizontal direction X, and connected in parallel to each other. The TRs 220 in the plurality of memory cells 201 in the vertical direction Z are connected in series to each other. The SNs 210 in the plurality of memory cells 201 in the vertical direction Z are connected in series to each other.

In the embodiments of the present disclosure, the three-dimensional memory array is described by taking the MA and the MB formed to be mirror symmetrical to each other as an example, and it will be understood that a three-dimensional memory array with higher memory density can be obtained by arranging the MA and the MB as described above.

With reference to FIG. 2 to FIG. 3, the substrate 100 includes, for example, silicon, such as monocrystalline silicon, polycrystalline silicon, or amorphous silicon. The substrate may also be selected from at least one of germanium (Ge), silicon germanium (SiGe), silicon carbide (SiC), gallium arsenide (GaAs), indium arsenide (InAs), and indium phosphide (InP).

Referring back to FIG. 1 and FIG. 2, in the embodiments of the present disclosure, the SN 210 and the TR 220 of each memory cell 201 are coupled in the horizontal direction, e.g., the first horizontal direction X, and connected in parallel to each other. Each SN 210 includes an upper electrode, a storage medium, and a lower electrode. Each TR 220 includes a source, a drain, and a gate. The two electrodes of the SN 220 are connected to the source and the drain of the TR 220, respectively, thereby achieving a parallel connection between the TR 220 and the SN 210. The TR 220 and the SN 210 in each memory cell 201 are connected in parallel, so that when the three-dimensional memory array is formed, by controlling the selection between the memory cells 201 by connecting the TRs in parallel, the crosstalk problem of a 3D structure, such as an X-POINT structure, can be effectively avoided.

With further reference to FIG. 1, the gates of the TRs 220 are connected to the WLs 202. The upper and lower layers of adjacent TRs 220 share the source and the drain. That is, between two adjacent layers of memory cells 201, the source of the lower layer of TR 201 is connected to the drain of the upper layer of TR 201, and the source and the drain are commonly connected to the same BL 203. The BL 203 connects the plurality of memory cells 201 along the vertical direction Z in series. That is, all TRs 220 of the same BL 203 are connected in series, and/or all SNs 210 of the same BL 203 are connected in series. When read and write operations are performed, the target TR TRx corresponding to the target SN SNx is turned off while turning on all the other TRs, and different voltage biases are applied to an upper end and a lower end of the BL 203, namely a BL end and a BL′ end, according to the requirements of writing 0 or writing 1. The BL end may be electrically connected to an external circuit through a contact plug for power supply, and the BL′ end is connected to the substrate 100 and may be powered by an underlying logic circuit or a hybrid bonding way.

It is noted that in an embodiment of the present disclosure, if the channel of the TR 220 is made of a conductive material (e.g., ITO material shown later) or a negative Vt semiconductor material (e.g., the TR 220 is a P-type TR), when read and write operations are performed, the target TR TRx is turned off by applying a negative voltage to the WL of the target TR TRx corresponding to the target SN SNx, and different voltage biases are applied to the BL end and the BL′ end according to the requirements of writing 0 or writing 1. In another embodiment of the present disclosure, if the channel of the TR 220 is made of a positive Vt semiconductor material (e.g., the TR 220 is an N-type TR), when read and write operations are performed, all other TRs except the target TR TRx corresponding to the target SN SNx are turned on by applying a positive voltage to the WLs of the TRs (only the target TR TRx is turned off), and different voltage biases are applied to the BL end and the BL′ end according to the requirements of writing 0 or writing 1.

With further reference to FIG. 1 to FIG. 3, a plurality of SNs 210 are stacked along the vertical direction Z and, for example, connected in series to each other. As an example, the plurality of SNs 210 stacked along the vertical direction Z include a plurality of electrodes 211 and a plurality of storage media 212, and the electrodes 211 and the storage media 212 are alternately arranged along the vertical direction Z. One of the electrodes is shared between adjacent SNs 210 in the plurality of memory cells 201 in the vertical direction Z. That is to say, between the adjacent SNs 210, the upper electrode of the lower layer of SN is also the lower electrode of the upper layer of SN, so that based on the structure of the embodiments of the present disclosure, the upper and lower layers of adjacent memory cells share one of the electrodes. The process is simple, the plurality of SNs 210 are stacked along the vertical direction Z and connected in series to each other, and the maximum vertical stacking density can be achieved.

With reference to FIG. 2 and FIG. 3, the plurality of electrodes 211 and the plurality of storage media 212 are alternately arranged along the vertical direction Z, and the electrodes 211 and the storage media 212 may, for example, extend along the horizontal direction, e.g., the first horizontal direction X, so as to form plate-shaped horizontal capacitors. In the embodiments of the present disclosure, the storage node capacitor is arranged horizontally, so that not only the structure is simple, but also the area may be increased as required to improve the capacitance. The material of the electrodes 211 may be at least one of metal, metal nitride, or metal oxide, for example, tungsten (W), molybdenum (Mo), titanium (Ti), tantalum (Ta), platinum (Pt), iridium (Ir), titanium nitride (TiN), tungsten nitride (WN), tantalum nitride (TaN), iridium oxide (IrO2), titanium oxide (TiO).

It is noted that the SNs 210 in the memory cells 201 may be selected from any one of a capacitive storage medium (e.g., DRAM), a ferroelectric storage medium (e.g., FeRAM and FTJ), a magnetic storage medium (e.g., MRAM), a phase change storage medium (e.g., PCRAM), and a resistive storage medium (e.g., RRAM). The SNs in the embodiments of the present disclosure have excellent extensibility and can be applied to various types of memories. For the storage medium in the embodiments of the present disclosure, a ferroelectric storage medium is taken as an example, and a non-volatile memory such as a FeRAM is formed. The material of the ferroelectric storage medium may be selected from at least one of lead zirconium titanate (PZT), strontium bismuth titanate (SBT), bismuth lanthanum titanate (BLT), barium strontium titanate (BST), hafnium oxide (HfO2) having ferroelectricity, zirconium oxide (ZrO) having ferroelectricity, and hafnium zirconium oxide (HfZrO2) having ferroelectricity. Further, the ferroelectric storage medium may also use various doped elements, such as lanthanum (La), yttrium (Y), titanium (Ti), and aluminum (Al).

Referring back to FIG. 1 to FIG. 3, a plurality of TRs 220 are stacked along the vertical direction Z and, for example, connected in series to each other. The plurality of TRs 220 include a plurality of gates 221, a dielectric layer 222, and a semiconductor layer 223. The semiconductor layer 223, the dielectric layer 222, and the gates 221 are sequentially arranged on one side of the plurality of SNs 210 in the horizontal direction, e.g., the first horizontal direction X, and coupled to the SNs 210 in the horizontal direction, e.g., the first horizontal direction X. The semiconductor layer 223 and the dielectric layer 222 extend along the vertical direction Z, so that the TRs extend mainly in the vertical direction Z, and the footprint in the horizontal direction is small. As such, it not only provides a spatial place for forming an SN with a larger capacitance, but also facilitates forming the maximum stacking density in the vertical direction Z.

With further reference to FIG. 2 to FIG. 3, the plurality of gates 221 are separately spaced apart along the vertical direction Z, and the gates 221 are connected to the WLs 202. For example, the gates 221 are parts of the WLs 202. The material of the gates 221 may be at least one of doped polycrystalline silicon, metal, metal nitride, or metal carbide, for example tungsten (W), molybdenum (Mo), titanium (Ti), tantalum (Ta), titanium nitride (TiN), tungsten nitride (WN), tantalum nitride (TaN), titanium aluminum nitride (TiAlN), tantalum aluminum nitride (TaAlN), titanium aluminum carbide (TiAlC), titanium aluminum carbonitride (TiAlCN), titanium silicon carbonitride (TiSiCN), tantalum aluminum carbonitride (TaAlCN), and tantalum silicon carbonitride (TaSiCN). It is noted that in the embodiments of the present disclosure, the electrodes 221 and the gates 211 are made of different materials so as to have different etching selectivities in the manufacturing process, thereby forming a three-dimensional memory array with a desired structure.

With further reference to FIG. 2 and FIG. 3, the dielectric layer 222 is arranged between the SNs 210 and the gates 221, and the dielectric layer 222 is a continuum extending along the vertical direction Z and is shared with a plurality of dielectric layers 222 of the plurality of TRs 220 along the vertical direction Z. The dielectric layer 222 may be selected from at least one of silicon oxide, silicon nitride, silicon oxynitride, and a high-k dielectric film having a higher dielectric constant than that of silicon oxide, for example hafnium oxide (HfO2), hafnium silicate (HfSiO), hafnium oxynitride (HfON), hafnium silicon oxynitride (HfSiON), hafnium aluminum oxide (HfAlO3), lanthanum oxide (LaO), lanthanum aluminum oxide (LaAlO), zirconium oxide (ZrO), zirconium silicate (ZrSiO), zirconium oxynitride (ZrON), zirconium silicon oxynitride (ZrSiON), titanium oxide (TiO2), barium strontium titanium oxide (BaSrTiO), barium titanium oxide (BaTiO), strontium titanium oxide (SrTiO), yttrium oxide (YO), aluminum oxide (Al2O3), tantalum oxide (Ta2O3), and lead scandium tantalum oxide (PbScTaO).

With further reference to FIG. 2 and FIG. 3, the semiconductor layer 223 is arranged between the SNs 210 and the dielectric layer 222. The semiconductor layer 223 has two opposite surfaces, one surface contacts the SNs 210 and is coupled to the SNs 210 in the horizontal direction, and the other surface contacts the dielectric layer 222. The dielectric layer 222 is arranged on a surface of the semiconductor layer 223. The semiconductor layer 223 is the same as the dielectric layer 222, and the semiconductor layer is also a continuum extending along the vertical direction Z. The semiconductor layer 223 is connected to the BL 203. For example, the semiconductor layer 223 is part of the BL 203 and may be shared with the BL 203, so that the plurality of semiconductor layers 223 of the plurality of TRs 220 along the vertical direction Z are shared through the BL 203. That is, the plurality of TRs 220 are connected in series.

With further reference to FIG. 2, the semiconductor layer 223 includes a plurality of source/drain regions 223a and a plurality of channel regions 223b, and the source/drain regions 223a and the channel regions 223b are alternately arranged in the semiconductor layer 223. One of the source/drain regions 223a is shared between adjacent TRs 220 in the plurality of memory cells 201 in the vertical direction Z. That is to say, between the adjacent TRs 220, the source/drain region of the lower layer of TR is also the drain/source region of the upper layer of TR, so that based on the structure of the embodiments of the present disclosure, the upper and lower layers of adjacent memory cells share one of the source/drain regions. The source/drain structures are not complex, the process is simple, and the maximum vertical stacking density can be achieved. The semiconductor layer 223 in the embodiments of the present disclosure may be made of a two-dimensional material, such as monocrystalline silicon, polycrystalline silicon, and molybdenum disulfide (MoS2); or an oxide semiconductor material, for example, at least one of indium tin oxide (ITO), indium gallium zinc oxide (IGZO), indium zinc oxide (IZO), and indium gallium oxide (IGO).

With further reference to FIG. 2, the semiconductor layer 223 is conformally arranged on surfaces of the plurality of electrodes 211 and surfaces of the plurality of storage media 212 in the SNs 210 stacked in the vertical direction Z. The plurality of source/drain regions 223a in the semiconductor layer 223 are connected to the plurality of electrodes 211, and the plurality of channel regions 223b in the semiconductor layer are connected to the plurality of storage media 212, such that the TR 210 and the SN 220 are coupled in the horizontal direction, e.g., the first horizontal direction X, and connected in parallel to each other.

With further reference to FIG. 2 to FIG. 3, in an embodiment of the present disclosure, the semiconductor layer 223 has a plurality of recesses. For example, the recesses protruding towards the storage media 212, for example, a ferroelectric layer, are formed at the channel regions 223b. Specifically, when the dimension of each storage medium 212 in the horizontal direction, e.g., the first horizontal direction X, is smaller than the dimension of each electrode 211, so that the semiconductor layer 223 is conformally arranged on the surfaces of the plurality of electrodes 211 and the surfaces of the plurality of storage media 212 from one side of the first horizontal direction X, and the semiconductor layer 223 forms the plurality of recesses. The dielectric layer 222 is conformally arranged on the surface of the semiconductor layer 223 and also has respective recesses. The gates 221 are arranged at the recesses, and thus the gates correspond to the channel regions 223b and the storage media 212. In the embodiment, each gate 221 or WL 202 is flush with one side of the dielectric layer 222 and does not extend out from a lateral side of the dielectric layer 222. The recesses facilitate forming the stable gates 221, but are not limited thereto. In other embodiments, such as FIG. 4 shown later, other topographies of the TRs 220 are shown. The semiconductor layer 230 extends along the vertical direction Z and has a flush surface, and the semiconductor layer 230 is conformally arranged on the surfaces of the plurality of electrodes 211 and the surfaces of the plurality of storage media 212, for example, ferroelectric layers, from one side of the first horizontal direction X. The dielectric layer 222 also has a flush surface and is arranged on the surface of the semiconductor layer 223. The gates 221 are arranged on the surface of the dielectric layer 222 and correspond to the channel regions 223b of the semiconductor layer 223. It can be understood that any scheme or topography that couples the TR and SN in the horizontal direction and connects the two in parallel to each other is intended to fall within the protection scope of the present disclosure.

With further reference to FIG. 3, an insulating dielectric layer 224 may be further provided between the storage media 212 and the channel regions 223b of the semiconductor layer 223. For example, the insulating dielectric layer may be selected from at least one of silicon oxide (SiOx), silicon nitride (SiNx), silicon carbide (SiC), aluminum oxide (AlOx), aerogel, or airgap, The insulating dielectric layer 224 can reduce the capacitive coupling between the channel regions 223b of the TRs 220 and the upper and lower electrodes 211 of the SNs 210, and may select, for example, a material having a low-k dielectric constant.

Referring back to FIG. 1 to FIG. 3, the MA in the three-dimensional memory array further includes a plurality of WLs 202 and at least one BL 203. The plurality of WLs 202 are spaced apart along the vertical direction Z and connected to the TRs 220, e.g., the gates 221, in the plurality of memory cells 201 in the vertical direction Z, respectively. Specifically, the gates 221 may be parts of the WLs 202. Each WL 202 extends along the horizontal direction, e.g., a second horizontal direction Y (the second horizontal direction Y is, for example, perpendicular to the first horizontal direction X), so that for example, when the plurality of memory cells 201 in the MA are spaced apart along the second horizontal direction Y, the TRs in the plurality of memory cells 201 in the second horizontal direction Y may be connected. The BL 203 extends along the vertical direction Z and is connected to the TRs 220 in the plurality of memory cells 201 in the vertical direction Z, for example, the semiconductor layer 223. The BL 203 is shared with the semiconductor layer 223 in the embodiments of the present disclosure. That is, the semiconductor layer 223 also plays a role of the BL 203 and leads out signals of the TRs 220. The TRs in the plurality of memory cells 201 in the second horizontal direction Y are connected by a WL, accordingly.

FIG. 4 shows a cross-sectional view of another embodiment of a three-dimensional memory array. In the embodiment, the semiconductor layer 223 and the dielectric layer 222 do not include the recesses and have vertical surfaces. The gates 221 or the WLs 202 are arranged on the lateral side of the dielectric layer 222, e.g., one side of the dielectric layer 222 in the first horizontal direction X, and extend along the second horizontal direction Y. The three-dimensional memory array in FIG. 4 is substantially the same as the three-dimensional memory array described with reference to FIG. 1 to FIG. 3. In the embodiment, the TR 220 has a more regular topography and a simpler structure, which is conducive to improving the performance of the device.

The embodiments of the present disclosure further provide a method for manufacturing a three-dimensional memory array. The method includes forming an MA. Forming the MA includes: forming a plurality of memory cells stacked along a vertical direction; forming a plurality of WLs spaced apart along the vertical direction; and forming at least one BL extending along the vertical direction. Each memory cell includes a TR and an SN coupled in a horizontal direction and connected in parallel to each other. The TRs in the plurality of memory cells in the vertical direction are connected in series to each other, and/or the SNs in the plurality of memory cells in the vertical direction are connected in series to each other. The plurality of WLs are connected to the TRs in the plurality of memory cells in the vertical direction, respectively. The BL is connected to the TRs in the plurality of memory cells in the vertical direction.

FIG. 5 to FIG. 18 are cross-sectional views of stages in a method for manufacturing a three-dimensional memory array according to an embodiment of the present disclosure. In the embodiments of the present disclosure, by taking the MA and the MB formed to be mirror symmetrical as an example, it can be understood that more memory cell arrays can be simultaneously formed, these memory cell arrays are spaced apart on the substrate 100, and the memory cell arrays may be isolated from each other by isolation layers (not all shown) to protect the three-dimensional memory array. The method for manufacturing a three-dimensional memory array according to an embodiment of the present disclosure will be described in detail below with reference to FIG. 5 to FIG. 18.

With reference to FIG. 5, a substrate 100 is provided, and a stack layer of a plurality of electrode materials 211′ and a plurality of storage medium materials, e.g., ferroelectric materials 212′, alternately arranged is formed on the substrate 100. The electrode materials 211′ are deposited first and cover a surface of the substrate 100, followed by the deposition of the storage medium materials 212′. Multiple depositions are alternately performed.

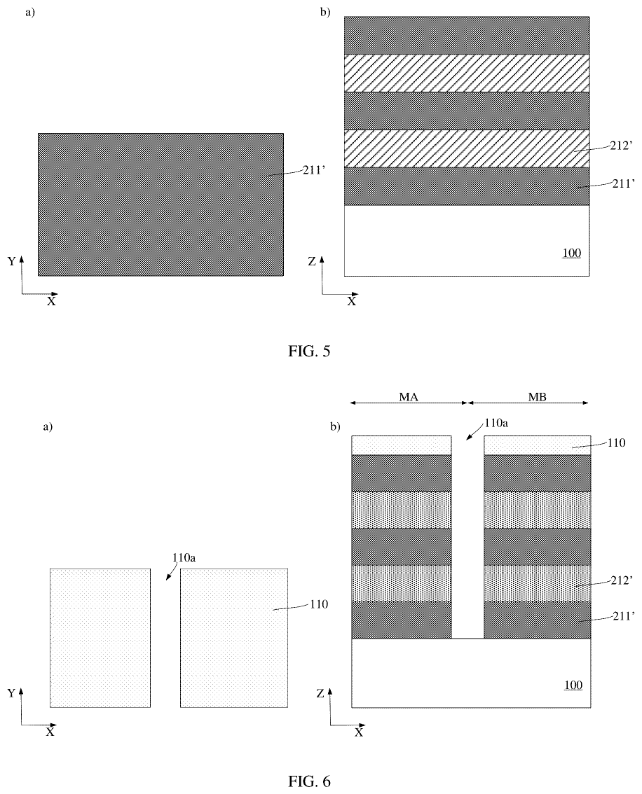

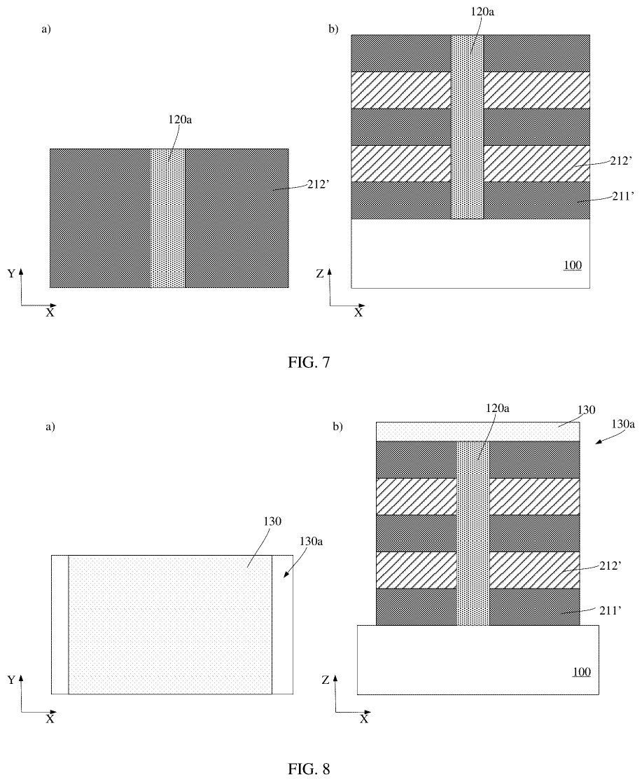

With reference to FIG. 6 to FIG. 7, a first mask layer 110 is formed on a surface of the stack layer, and the first mask layer 110 is patterned. At least one first opening exposing the surface of the stack layer is formed in the first mask layer 110, and the stack layer is etched downwards along the first opening to form at least one first trench 110a penetrating through the stack layer. The first trench 110a extends along a horizontal direction, e.g., a second horizontal direction Y, and the first trench 110a divides the stack layer into a plurality of memory cell arrays spaced apart in a first horizontal direction X, for example, into an MA region and an MB region. Then, with reference to FIG. 7, an isolation material, such as silicon oxide, is deposited by backfilling, and the entire surface is planarized to form a first isolation layer 120a, such that the first isolation layer 120a is flush with the surface of the stack layer, and the first isolation layer 120a isolates the plurality of memory cell array regions.

With reference to FIG. 8, a second mask layer 130 is formed on the surface of the stack layer and the surface of the first isolation layer 120a, and the second mask layer 130 is patterned. At least two second openings exposing the surface of the stack layer are formed in the second mask layer, and the stack layer is etched downwards along the second openings to form at least two second trenches 130a penetrating through the stack layer. The at least two second trenches 130a are spaced apart along the first horizontal direction X, and each second trenches 130a extends along the second horizontal direction Y and is parallel to the first trench 110a. The at least two second trenches 130a are arranged on one side of the MA away from the MB and one side of the MB away from the MA, respectively, facilitating the simultaneous formation of TRs on two opposite sides of the MA and the MB.

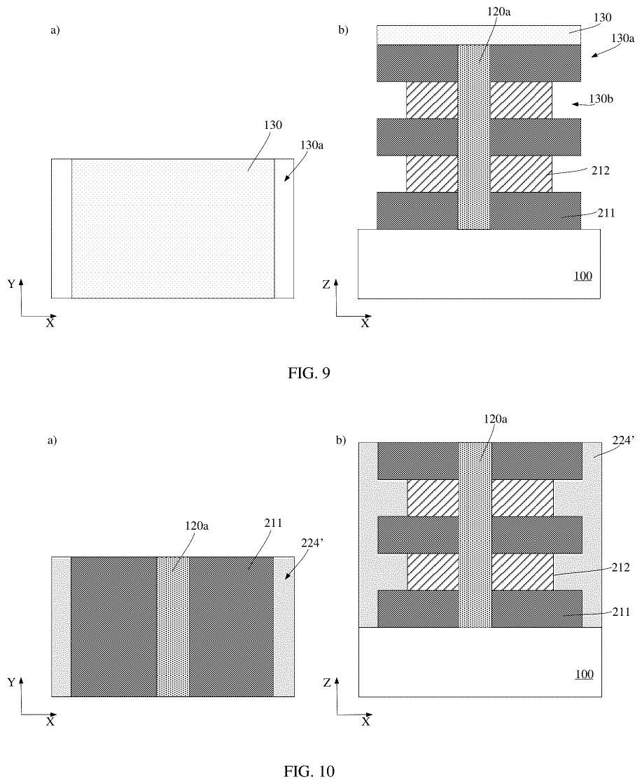

Then, with reference to FIG. 9, parts of the storage medium materials 212′ in the stack layer are laterally etched, for example, by a dry etching process, along the second trench 130a to form a plurality of side cavities 130b spaced apart along a vertical direction z. The plurality of side cavities 130b provide reserved positions for subsequently formed gates 221. In this case, a remaining part of the electrode materials 211′ and a remaining part of the storage medium materials 212′ in the stack layer are formed into electrodes 211 and storage media 212, respectively. The plurality of electrodes 211 and the plurality of storage media 212 are alternately arranged along the vertical direction Z, forming a plurality of SNs 210 connected in series in the vertical direction Z.

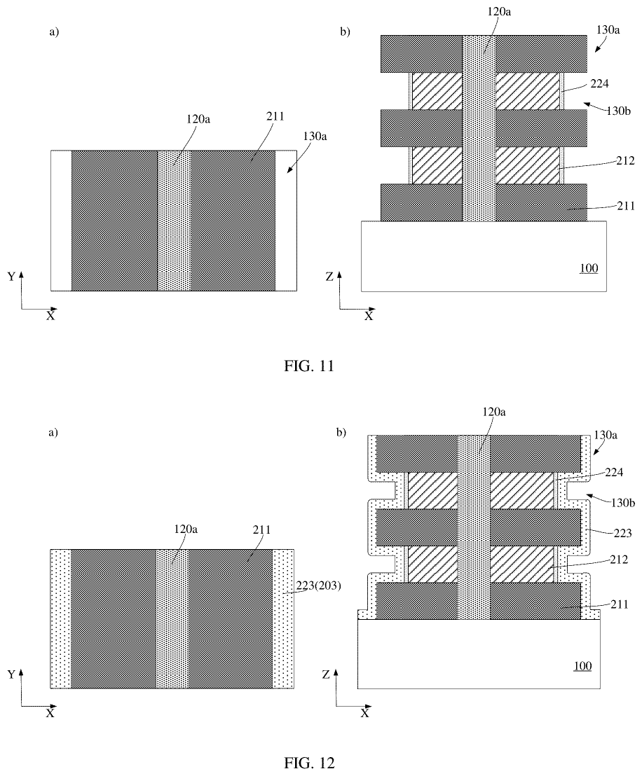

With reference to FIG. 10 to FIG. 11, the plurality of side cavities 130b communicate with the second trench 130a to form a comb-shaped opening space. For example, an insulating dielectric material 224′ is deposited along the comb-shaped opening space; after the insulating dielectric material 224′ is planarized, part of the insulating dielectric material 224′ is removed along the second trench 130a and the plurality of side cavities 130b again. The insulating dielectric material 224′ arranged on surfaces of the storage media 212 within the plurality of side cavities 130b is retained, and in this case, a remaining part of the insulating dielectric material 224′ is formed into a plurality of insulating dielectric layers 224. It can be understood that a subsequent semiconductor layer 223 may be directly formed without forming the insulating dielectric layer 224. In this case, the semiconductor layer 223 will be conformally arranged on surfaces of the plurality of electrodes 211 and the surfaces of the plurality of storage media 212.

Then, with reference to FIG. 12, the semiconductor layer 223 is conformally formed along the surfaces of the plurality of electrodes 211 exposed by the second trench 130a and surfaces of the plurality of insulating dielectric layers 224 exposed by the plurality of side cavities 130b. The semiconductor layer 223 extends along the vertical direction, and remaining spaces of the plurality of side cavities 130b are formed into a plurality of recesses of the semiconductor layer 223. The semiconductor layer 223 is arranged on one side of the SNs 210 along the first horizontal direction X and coupled to the SNs 210 in the horizontal direction, e.g., the first horizontal direction X. The semiconductor layer 223 in contact with the electrodes 211 is partially formed into source/drain regions 223a, and the semiconductor layer 223 in contact with the storage media 212 or in contact with the insulation layers 224 on the surfaces of the storage media 212 is formed into channel regions 223b. Furthermore, it is noted that in an embodiment of the present disclosure, the semiconductor layer 223 is shared with the BL 203, and thus, the BL 203 is formed while forming the semiconductor layer 223.

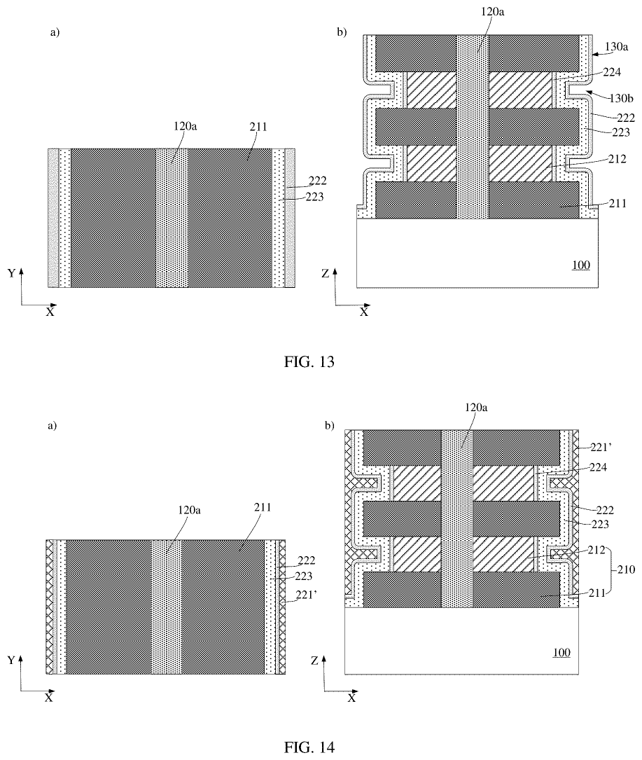

With reference to FIG. 13, a dielectric layer 222 continues to be formed along a surface of the semiconductor layer 223 exposed by the second trench 130a and the plurality of side cavities 130b. The dielectric layer 222 extends along the vertical direction Z and is arranged on the surface of the semiconductor layer 223.

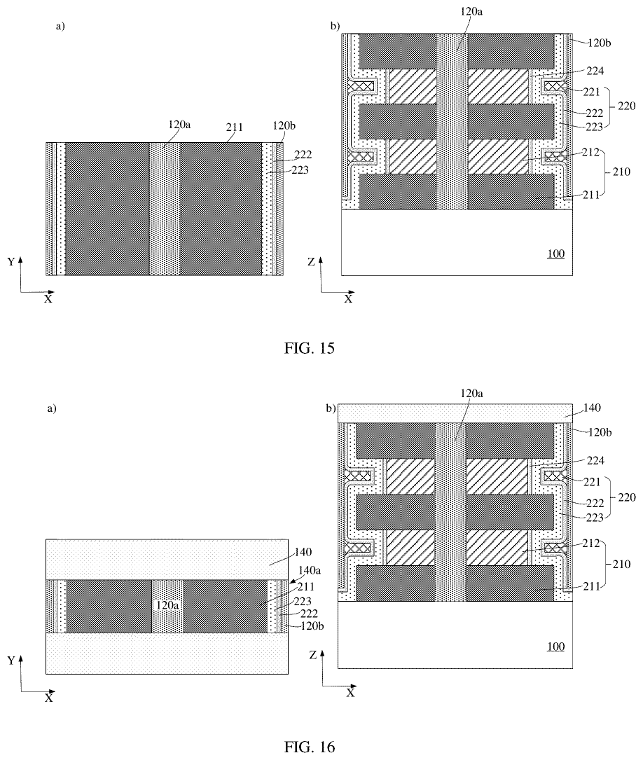

With reference to FIG. 14 and FIG. 15, a gate material 221′ is deposited within a remaining space of the second trench 130a and remaining spaces of the plurality of side cavities 130b. After deposition, with reference to FIG. 15, the gate material 221′ is etched back, the gate material 221′ in the remaining space of the second trench 130a is removed, while the gate material in the remaining spaces of the plurality of side cavities 130b is retained. In this case, a remaining part of the gate material 221′ is arranged on a surface of the dielectric layer 222 and spaced apart in the vertical direction Z to form a plurality of gates 221. The plurality of gates 221 are arranged in the remaining spaces of the plurality of side cavities 130b, respectively. That is, the plurality of gates are arranged within the plurality of recesses of the semiconductor layer 223 and correspond to the channel regions 230b of the semiconductor layer 223. It is noted that the gate material 221′ and the electrode material 211′ are different in the embodiments of the present disclosure, so as to ensure that the etching selectivities of the two are different in the etching process to adapt to various patterning processes. In the embodiments of the present disclosure, the gates 221 are parts of WLs 202. Thus, the plurality of WLs 202 are also simultaneously formed. In this case, TRs 220 in a plurality of memory cells 201 in the vertical direction are connected in series to each other, and the TRs 220 and the SNs 210 are coupled in the horizontal direction and connected in parallel to each other.

With further reference to FIG. 15, a second isolation layer 120b, such as silicon oxide, is backfilled in the remaining space of the second trench 130a. The second isolation layer 120b is similar to the first isolation layer 120a. The second isolation layer also extends along the second horizontal direction Y, and penetrates through the stack layer to isolate the plurality of memory cell arrays.

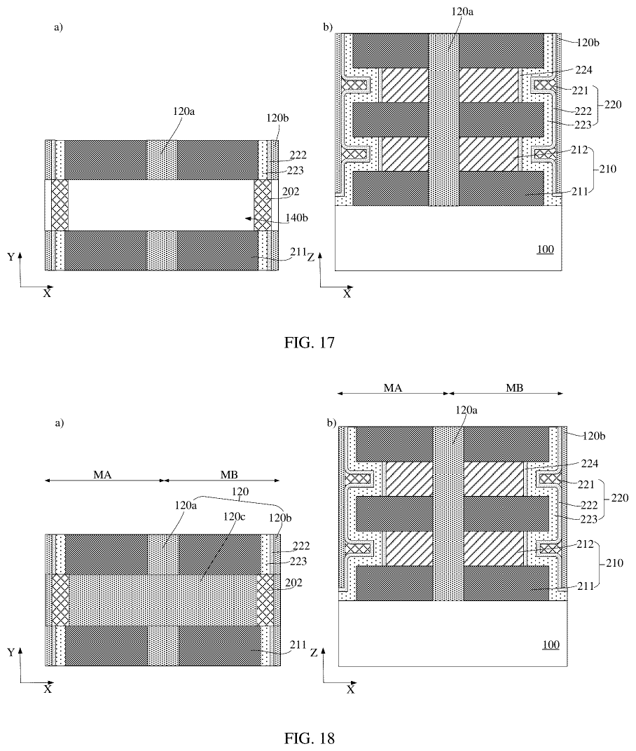

Then, with reference to FIG. 16 to FIG. 18, a third mask layer 140 covering the entire structure may be formed again, the third mask layer 140 is patterned, and at least one third opening 140a is formed in the third mask layer 140. The third opening 140a extends along the first horizontal direction X and is used for etching the stack layer to form a plurality of memory cells 201 spaced apart in the second horizontal direction Y. Specifically, with reference to FIG. 17, the electrodes 211 and the storage media 212 in the stack layer are etched downwards along the third opening 140a, and the dielectric layer 222, the semiconductor layer 223, and the insulating dielectric layer 224 are etched to form a third trench 140b. The third trench 140b cuts off the layers in the second horizontal direction Y. The gates 221 or the WLs 202 are retained without being etched and removed and still extend along the second horizontal direction Y, so that TRs of the plurality of memory cells 201 in the second horizontal direction Y may be connected. Then, with reference to FIG. 18, an isolation material, such as silicon oxide, is deposited by backfilling into the third trench 140b, and the entire surface is planarized to form a third isolation layer 120c. The third isolation layer 120c extends along the first horizontal direction x, penetrates through the stack layer, and penetrates through the dielectric layer 222, the semiconductor layer 223, and the region between the adjacent WLs 202. The third isolation layer 120c isolates the plurality of memory cells 201 spaced apart in the second horizontal direction y in the MA and the MB from each other. The first isolation layer 120a, the second isolation layer 120b, and the third isolation layer 120c are collectively referred to as an isolation layer 120. The isolation layer isolates the three-dimensional memory array on the substrate 100.

In the embodiments of the present disclosure, a three-dimensional memory array is provided. A plurality of memory cells stacked along a vertical direction is provided, each memory cell includes a TR and an SN coupled in a horizontal direction, the TR and the SN are connected in parallel to each other, the TRs in the plurality of memory cells in the vertical direction are connected in series to each other, and/or the SNs in the plurality of memory cells in the vertical direction are connected in series to each other. Based on the above solutions, the wiring is simple, and the maximum vertical stacking density is achieved. In addition, by controlling the selection between adjacent storage bits by connecting the TRs in parallel, the crosstalk problem of the existing three-dimensional memory structure is effectively avoided, and the device performance is improved. The embodiments of the present disclosure may be applied to a non-volatile dual in-line memory module (NVDIMM) or a storage class memory (SCM) with high performance, high bandwidth, and high density.

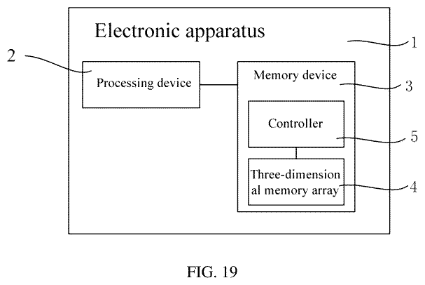

With reference to FIG. 19, the embodiments of the present disclosure further provide an electronic apparatus 1 having a memory function. The electronic apparatus includes a processing device 2 and a memory device 3 electrically connected to the processing device. The memory device 3 includes the three-dimensional memory array 4 described in FIG. 1 to FIG. 18 above and a controller 5 configured to control the reading and writing of the three-dimensional memory array 4. The electronic apparatus may be a terminal apparatus, such as a personal computer, a mobile phone, a pad, consumer electronics, for example, a smart appliance, an autonomous vehicle (automotive), a smart wearable product (e.g., a smart watch and a smart bracelet), a virtual reality (VR) apparatus, and an augmented reality (AR) apparatus; and may also be a server, a data center, and the like. The memory device 3 may be, for example, the NVDIMM or the SCM with high performance, high bandwidth, and high density. The memory function in the electronic apparatus 1 may be implemented by these memory devices 3.

In some embodiments, the processing device 2 and the memory device 3 may be two separate chips forming a stand-alone memory. In other embodiments, the memory device 3 and the processing device 2 may also be integrated into the same chip to form an embedded memory. The electronic apparatus 1 and the three-dimensional memory array 4 described in FIG. 1 to FIG. 18 above can solve the same technical problems and achieve the same expected effects.

The above description is only the specific embodiments of the present disclosure, but the protection scope of the present disclosure is not limited thereto; changes or substitutions that any one skilled in the art can easily think of within the technical scope disclosed by the present disclosure shall all fall within the protection scope of the present disclosure. Therefore, the protection scope of the present disclosure shall be defined by the protection scope of the claims.

1. A three-dimensional memory array, comprising: a first memory cell array comprising:
a plurality of memory cells stacked along a vertical direction, each one of the plurality of memory cells comprising a transistor and a storage node coupled in a horizontal direction and connected in parallel to each other, wherein the transistors in the plurality of memory cells in the vertical direction are connected in series to each other, and/or the storage nodes in the plurality of memory cells in the vertical direction are connected in series to each other;
a plurality of word lines spaced apart along the vertical direction and connected to the transistors in the plurality of memory cells in the vertical direction, respectively; and
at least one bit line extending along the vertical direction and connected to the transistors in the plurality of memory cells in the vertical direction.

2. The three-dimensional memory array according to claim 1, wherein the storage nodes in the plurality of memory cells in the vertical direction connected in series to each other comprise:
a plurality of electrodes and a plurality of storage media alternately arranged along the vertical direction, wherein one of the plurality of electrodes is shared between adjacent storage nodes in the plurality of memory cells in the vertical direction.

3. The three-dimensional memory array according to claim 2, wherein each one of the plurality of storage media is selected from any one of a capacitive storage medium, a ferroelectric storage medium, a magnetic storage medium, a phase change storage medium, and a resistive storage medium.

4. The three-dimensional memory array according to claim 1, wherein the transistors in the plurality of memory cells in the vertical direction connected in series to each other comprise:
a semiconductor layer extending along the vertical direction, arranged on one side of the storage nodes in the horizontal direction, and coupled to the storage nodes in the horizontal direction, the semiconductor layer being connected to the bit line;
a dielectric layer extending along the vertical direction and arranged on a surface of the semiconductor layer; and
a plurality of gates separately spaced apart along the vertical direction and arranged on a surface of the dielectric layer, the plurality of gates being connected to the plurality of word lines,
wherein the semiconductor layer comprises a plurality of source/drain regions and a plurality of channel regions alternately arranged, and one of the plurality of source/drain regions is shared between adjacent transistors in the plurality of memory cells in the vertical direction.

5. The three-dimensional memory array according to claim 4, wherein the semiconductor layer is selected from at least one of monocrystalline silicon, polycrystalline silicon, molybdenum disulfide, indium tin oxide, indium gallium zinc oxide, indium zinc oxide, and indium gallium oxide.

6. The three-dimensional memory array according to claim 4, wherein the semiconductor layer is conformally arranged on surfaces of the plurality of electrodes and the plurality of storage media of the storage nodes, wherein the plurality of source/drain regions in the semiconductor layer are connected to the plurality of electrodes, and the plurality of channel regions in the semiconductor layer are connected to the plurality of storage media, such that the transistor and the storage node are coupled in the horizontal direction and connected in parallel to each other.

7. The three-dimensional memory array according to claim 6, wherein the semiconductor layer has a plurality of recesses protruding towards the plurality of storage media, wherein the plurality of gates are arranged within the plurality of recesses, respectively.

8. The three-dimensional memory array according to claim 6, wherein the semiconductor layer and the dielectric layer both extend along the vertical direction and have vertical surfaces, and the plurality of gates are arranged on one side of the dielectric layer and connected to the plurality of word lines.

9. The three-dimensional memory array according to claim 6, wherein an insulating dielectric layer is further provided between the semiconductor layer and each one of the plurality of storage media.

10. The three-dimensional memory array according to claim 4, wherein the bit line is shared with the semiconductor layer of a plurality of transistors along the vertical direction.

11. The three-dimensional memory array according to claim 1, wherein the plurality of electrodes in the storage nodes and the plurality of gates in the transistors are made of different materials.

12. The three-dimensional memory array according to claim 1, further comprising a second memory cell array, wherein the first memory cell array and the second memory cell array are mirror symmetrical to each other.

13. A method for manufacturing a three-dimensional memory array, comprising forming a first memory cell array, comprising:
forming a plurality of memory cells stacked along a vertical direction, each one of the plurality of memory cells comprising a transistor and a storage node coupled in a horizontal direction and connected in parallel to each other, wherein the transistors in the plurality of memory cells in the vertical direction are connected in series to each other, and/or the storage nodes in the plurality of memory cells in the vertical direction are connected in series to each other;
forming a plurality of word lines spaced apart along the vertical direction, the plurality of word lines being connected to the transistors in the plurality of memory cells in the vertical direction, respectively; and
forming at least one bit line extending along the vertical direction, the bit line being connected to the transistors in the plurality of memory cells in the vertical direction.

14. The manufacturing method according to claim 13, further comprising forming a second memory cell array mirror symmetrical to the first memory cell array.

15. The manufacturing method according to claim 14, comprising:
providing a substrate and forming a stack layer comprising a plurality of electrode materials and a plurality of storage medium materials alternately arranged on the substrate;
forming at least one first trench penetrating through the stack layer, wherein the first trench extends along a second horizontal direction and divides the stack layer into at least the MA and the second memory cell array;
forming at least two second trenches penetrating through the stack layer, wherein the at least two second trenches are spaced apart along a first horizontal direction, and each one of the two second trenches extends along the second horizontal direction, the first horizontal direction being perpendicular to the second horizontal direction;
laterally etching parts of the plurality of storage medium materials along the two second trenches to form a plurality of side cavities spaced apart in the vertical direction, wherein a remaining part of the plurality of electrode materials and a remaining part of the plurality of storage medium materials are formed into a plurality of electrodes and a plurality of storage media, respectively;
conformally forming a semiconductor layer along surfaces of the plurality of electrodes exposed by the two second trenches and surfaces of the plurality of storage media exposed by the plurality of side cavities;
continuing to form a dielectric layer along a surface of the semiconductor layer exposed by the two second trenches and the plurality of side cavities; and
forming a plurality of gates on a surface of the dielectric layer exposed by the plurality of side cavities.

16. The manufacturing method according to claim 15, further comprising:
etching the plurality of electrodes and the plurality of storage media in the stack layer as well as the dielectric layer and the semiconductor layer downwards along the first horizontal direction to form a plurality of memory cells spaced apart in the second horizontal direction, wherein the plurality of word lines are retained and extend along the second horizontal direction, and each one of the plurality of word lines is connected to the transistors in the plurality of memory cells in the second horizontal direction.

17. The manufacturing method according to claim 15, wherein before forming the semiconductor layer, the method further comprises:
forming a plurality of insulating dielectric layers arranged on the surfaces of the plurality of storage media within the plurality of side cavities, respectively.

18. The manufacturing method according to claim 15, wherein the bit line is formed while forming the semiconductor layer.

19. The manufacturing method according to claim 13, wherein each one of the plurality of storage media in the storage nodes is selected from any one of a capacitive storage medium, a ferroelectric storage medium, a magnetic storage medium, a phase change storage medium, and a resistive storage medium.

20. An electronic apparatus, comprising:
a processing device; and
a memory device electrically connected to the processing device, the memory device comprising the three-dimensional memory array according to claim 1 and a controller configured to control reading and writing of the three-dimensional memory array.
